(19) United States
(12) Patent Application Publication
(10) Pub. No.: US 2026/0180433 A1
(43) Pub. Date: Jun. 25, 2026

(54) POWER SUPPLY AND POWER DISTRIBUTION METHOD

(71) Applicant: AcLeap Power Inc., Taipei City (TW)

(72) Inventors: Rongjun Deng, Shanghai City (CN); Terry Zhang, Shanghai City (CN); Xuehui Dai, Shanghai City (CN); Hardy Huang, Shanghai City (CN)

(21) Appl. No.: 19/260,750

(22) Filed: Jul. 7, 2025

(30) Foreign Application Priority Data
Dec. 23, 2024 (CN) 202411907173.1

(51) Int. Cl. H02M 1/32; H03K 3/017

(52) U.S. Cl. CPC H02M 1/32; H03K 3/017

(57) ABSTRACT

A power supply comprising a plurality of power conversion circuit groups, a plurality of sensing circuits and a control circuit is provided. Each power conversion circuit group comprises at least one power conversion circuit, and is configured to convert an input voltage into an output voltage according to a duty cycle. The sensing circuits are respectively coupled to the power conversion circuit groups, and are configured to sense the power conversion circuit groups to generate sensing signals. The control circuit is coupled to the power conversion circuit groups and the sensing circuits, configured to calculate compensation values based on the sensing signals and a plurality of group output voltages, and configured to reduce the duty cycle of the power conversion circuit groups based on the compensation values. The group output voltages are corresponding to a plurality of phases, and the phases are corresponding to the power conversion circuit groups.

### CROSS REFERENCE TO RELATED APPLICATIONS

The present application claims priority to Chinese Patent Application No. 202411907173.1 filed on Dec. 23, 2024, and titled “POWER SUPPLY AND POWER DISTRIBUTION METHOD”, which is hereby incorporated by reference in its entirety.

### TECHNICAL FIELD

The present disclosure relates to a power supply and a power distribution method. More particularly, the present disclosure relates to a power supply and a power distribution that adjusts duty cycle in a negative compensation manner.

### BACKGROUND

Power supplies are widely used in various modern electronic devices. Through the power supply, the input voltage can be converted into an operating voltage or current that meets the specifications of the electronic devices, and the output operating voltage or current can have a variety of different phases.

However, the power conversion circuits in power supplies used today are usually configured in a symmetric manner (in other words, each phase corresponds to one power conversion circuit), which limits the flexibility of configuration of the power supply. In addition, the power supplies used today usually use a combination of positive compensation and negative compensation to adjust the duty cycles of the power conversion circuits, but this adjustment method may cause the duty cycles of different phases to overlap, causing a short circuit in the power conversion circuits. Therefore, how to improve the flexibility of configuration of the power supply while avoiding short circuit problems is one of the issues in this field.

### BRIEF DESCRIPTION

A power supply is provided in the present disclosure. The power supply comprises a plurality of power conversion circuit groups, a plurality of sensing circuits and a control circuit. Each of the plurality of power conversion circuit groups comprises at least one power conversion circuit, and is configured to convert an input voltage into an output voltage according to a duty cycle. The plurality of sensing circuits are respectively coupled to the plurality of power conversion circuit groups, and are configured to sense the plurality of power conversion circuit groups to generate a plurality of sensing signals. The control circuit is coupled to the plurality of power conversion circuit groups and the plurality of sensing circuits. The control circuit is configured to calculate a plurality of compensation values based on the plurality of sensing signals and a plurality of group output voltages, and is configured to reduce the duty cycle of the plurality of power conversion circuit groups based on the plurality of compensation values. The plurality of group output voltages are corresponding to a plurality of phases, and the plurality of phases are corresponding to the plurality of power conversion circuit groups.

In some embodiments of the power supply, the duty cycles of the at least one power conversion circuit of any one of the plurality of power conversion circuit groups are the same as each other, and the at least one power conversion circuit of any one of the plurality of power conversion circuit groups are corresponding to the same one of the plurality of phases.

In some embodiments of the power supply, the at least one power conversion circuit are arranged in the power supply in a single in-line package (SIP).

In some embodiments of the power supply, the plurality of sensing signals are related to a plurality of circuit temperatures of the plurality of power conversion circuit groups. When a difference between one of the plurality of circuit temperatures and a balance temperature is greater than or equal to a temperature threshold, the plurality of compensation values are greater than zero and positively related to the difference between the one of the plurality of circuit temperatures and the balance temperature.

In some embodiments of the power supply, when the differences between each of the plurality of circuit temperatures and the balance temperature are smaller than the temperature threshold, the plurality of compensation values are equal to zero.

In some embodiments of the power supply, the plurality of sensing signals are related to a plurality of output currents of the plurality of power conversion circuit groups. When a difference between one of the plurality of output currents and a reference current is greater than or equal to a current threshold, the plurality of compensation values are greater than zero and positively related to the difference between the one of the plurality of output currents and the reference current. The reference current is positively related to the number of the at least one power conversion circuit in corresponding one of the plurality of power conversion circuit groups.

In some embodiments of the power supply, after the control circuit reduces the duty cycle of the plurality of power conversion circuit groups based on the plurality of compensation values, the plurality of power conversion circuit groups are configured to convert the input voltage into an adjusted output voltage and output a plurality of adjusted output currents. The plurality of sensing signals are related to the plurality of adjusted output currents, and the plurality of adjusted output currents are smaller than the plurality of output currents.

In some embodiments of the power supply, when a difference between one of the plurality of adjusted output currents and the reference current is greater than or equal to the current threshold, the control circuit is further configured to calculate a plurality of second compensation values based on the plurality of sensing signals and a plurality of adjusted group output voltages, and configured to reduce the duty cycle of the plurality of power conversion circuit groups based on the plurality of second compensation values. The plurality of second compensation values are positively related to the difference between the one of the plurality of adjusted output currents and the reference current, and the plurality of second compensation values are smaller than the plurality of compensation values and greater than zero.

In some embodiments of the power supply, when the differences between each of the plurality of output currents and the reference current are smaller than the current threshold, the plurality of compensation values are equal to zero.

In some embodiments of the power supply, the plurality of sensing circuits are further configured to sense the plurality of power conversion circuit groups to generate the plurality of sensing signals at an interval of an adjustment period.

A power distribution method suitable for a power supply is provided in the present disclosure. The power distribution method comprises: converting, by a plurality of power conversion circuit groups of the power supply, an input voltage into an output voltage, according to a duty cycle; sensing, by a plurality of sensing circuits of the power supply, the plurality of power conversion circuit groups, so as to generate a plurality of sensing signals; calculating, by a control circuit of the power supply, a plurality of compensation values, based on the plurality of sensing signals and a plurality of group output voltages; and reducing, by the control circuit, the duty cycle of the plurality of power conversion circuit groups, based on the plurality of compensation values. Each of the plurality of power conversion circuit groups comprises at least one power conversion circuit, the plurality of group output voltages are corresponding to a plurality of phases, and the plurality of phases are corresponding to the plurality of power conversion circuit groups.

In some embodiments of the power distribution method, the duty cycles of the at least one power conversion circuit of any one of the plurality of power conversion circuit groups are the same as each other, and the at least one power conversion circuit of the any one of the plurality of power conversion circuit groups are corresponding to the same one of the plurality of phases.

In some embodiments of the power distribution method, the at least one power conversion circuit are arranged in the power supply in a single in-line package (SIP).

In some embodiments of the power distribution method, the sensing, by the plurality of sensing circuits of the power supply, the plurality of power conversion circuit groups, so as to generate the plurality of sensing signals comprises: sensing, by the plurality of sensing circuits, a plurality of circuit temperatures of the plurality of power conversion circuit groups, as the plurality of sensing signals. In response to a difference between one of the plurality of circuit temperatures and a balance temperature being greater than or equal to a temperature threshold, the plurality of compensation values are greater than zero and positively related to the difference between the one of the plurality of circuit temperatures and the balance temperature.

In some embodiments of the power distribution method, in response to the differences between each of the plurality of circuit temperatures and the balance temperature being smaller than the temperature threshold, the plurality of compensation values are equal to zero.

In some embodiments of the power distribution method, the sensing, by the plurality of sensing circuits of the power supply, the plurality of power conversion circuit groups, so as to generate the plurality of sensing signals comprises: sensing, by the plurality of sensing circuits, a plurality of output currents output by the plurality of power conversion circuit groups, as the plurality of sensing signals. In response to a difference between one of the plurality of output currents and a reference current being greater than or equal to a current threshold, the plurality of compensation values are greater than zero and positively related to the difference between the one of the plurality of output currents and the reference current. The reference current is positively related to the number of the at least one power conversion circuit in corresponding one of the plurality of power conversion circuit groups.

In some embodiments of the power distribution method, after the reducing, by the control circuit, the duty cycle of the plurality of power conversion circuit groups, based on the plurality of compensation values, the power distribution method further comprises: converting, by the plurality of power conversion circuit groups, the input voltage into an adjusted output voltage; outputting, by the plurality of power conversion circuit groups, a plurality of adjusted output currents; and sensing, by the plurality of sensing circuits, the plurality of adjusted output currents output by the plurality of power conversion circuit groups, as the plurality of sensing signals. The plurality of adjusted output currents are smaller than the plurality of output currents.

In some embodiments of the power distribution method, after the sensing, by the plurality of sensing circuits, the plurality of adjusted output currents output by the plurality of power conversion circuit groups, as the plurality of sensing signals, the power distribution method further comprises: in response to a difference between one of the plurality of adjusted output currents and the reference current being greater than or equal to the current threshold: calculating, by the control circuit, a plurality of second compensation values, based on the plurality of sensing signals and a plurality of adjusted group output voltages; and reducing, by the control circuit, the duty cycle of the plurality of power conversion circuit groups, based on the plurality of second compensation values. The plurality of second compensation values are positively related to the difference between the one of the plurality of adjusted output currents and the reference current, and the plurality of second compensation values are smaller than the plurality of compensation values and greater than zero.

In some embodiments of the power distribution method, in response to the differences between each of the plurality of output currents and the reference current being smaller than the current threshold, the plurality of compensation values are equal to zero.

In some embodiments of the power distribution method, the sensing, by the plurality of sensing circuits of the power supply, the plurality of power conversion circuit groups, so as to generate the plurality of sensing signals further comprises: sensing, by the plurality of sensing circuits, the plurality of power conversion circuit groups, at an interval of an adjustment period, so as to generate the plurality of sensing signals.

Through the power supply and the power distribution method of the present disclosure, the flexibility of configuration of the power supply can be improved while avoiding the problem of short circuit in the adjusted power conversion circuit.

### BRIEF DESCRIPTION OF DRAWINGS

The present disclosure can be more fully understood by reading the following detailed description of the embodiment, with reference made to the accompanying drawings as follows.

FIG. 1 is a functional block diagram of a power supply in accordance with an embodiment of the present disclosure.

FIG. 2 is a schematic diagram of a control circuit performing negative compensation in accordance with some embodiments of the present disclosure.

FIG. 3 is a schematic diagram of an operation of a control circuit reducing duty cycles of power conversion circuit groups in accordance with some embodiments of the present disclosure.

FIG. 4 is a functional block diagram of a power supply in accordance with an embodiment of the present disclosure.

FIG. 5 is a flowchart of a power distribution method in accordance with some embodiments of the present disclosure.

### DETAILED DESCRIPTION

Reference will now be made in detail to the present embodiments of the disclosure, examples of which are illustrated in the accompanying drawings. Wherever possible, the same reference numbers are used in the drawings and the description to refer to the same or like parts.

As used in the present disclosure, the singular forms “a”, “one” and “the” are also intended to include plural forms, unless the context clearly indicates otherwise. It will be further understood that when used in this specification, the terms “comprises (comprising)” and/or “includes (including)” designate the existence of stated features, regions, integers, activities, operations, elements and/or components, but the existence or addition of one or more other features, regions, integers, activities, operations, elements, components, and/or groups thereof are not excluded.

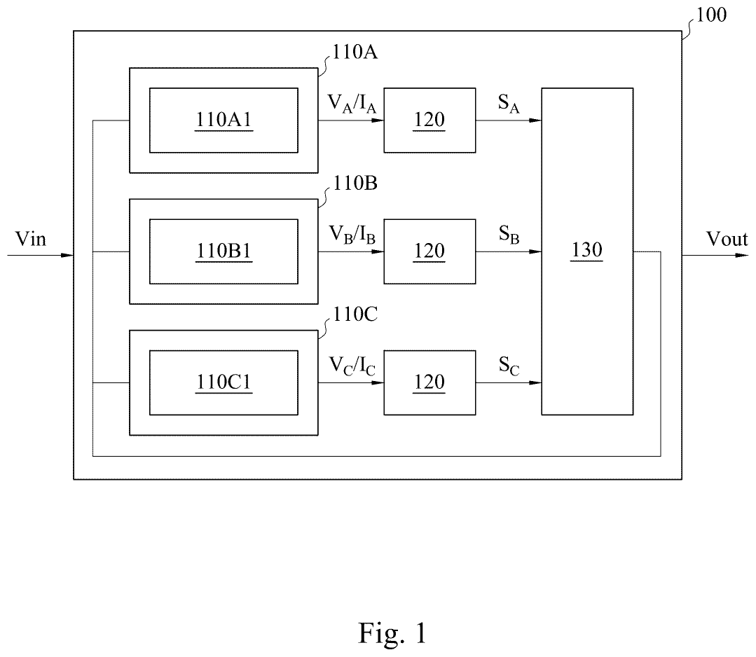

FIG. 1 is a functional block diagram of a power supply 100 in accordance with an embodiment of the present disclosure. The power supply 100 is configured to receive an input voltage Vin and convert the input voltage Vin into a total output voltage Vout. In some embodiments, the power supply 100 comprises power conversion circuit groups 110A, 110B, 110C, three sensing circuits 120 and a control circuit 130.

In the embodiment of FIG. 1, each of the power conversion circuit groups 110A, 110B and 110C comprises a power conversion circuit. For example, the power conversion circuit group 110A comprises a power conversion circuit 110A1, the power conversion circuit group 110B comprises a power conversion circuit 110B1, and the power conversion circuit group 110C comprises a power conversion circuit 110C1. The power conversion circuit groups 110A, 110B and 110C are configured to receive the input voltage Vin, and respectively convert the input voltage Vin into group output voltages V_{A}, V_{B} and V_{C} according to their duty cycles. In some embodiments, the power conversion circuits 110A1, 110B1 and 110C1 are arranged in the power supply 110 in a single in-line package (SIP).

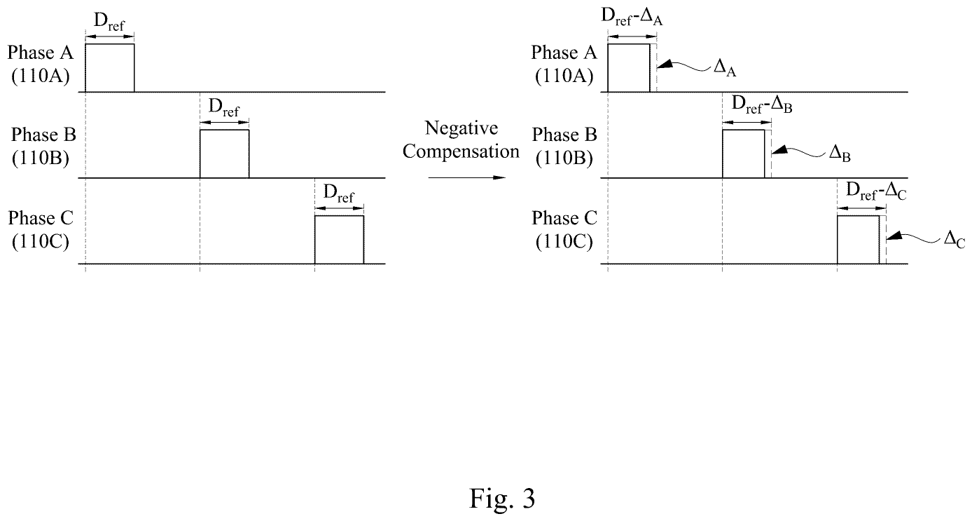

In some embodiments, the group output voltages V_{A}, V_{B} and V_{C} are respectively corresponding to different phases (for example, phase A, phase B and phase C in FIG. 3 as described in subsequent paragraphs), and these phases are respectively corresponding to the power conversion circuit groups 110A, 110B and 110C. In other words, the power conversion circuit groups 110A, 110B and 110C are activated in different phases (namely, different periods within a cycle) and respectively convert the input voltage Vin into the group output voltages V_{A}, V_{B} and V_{C}.

The three sensing circuits 120 are coupled to the power conversion circuit groups 110A, 110B and 110C respectively, and are configured to sense the power conversion circuit groups 110A, 110B and 110C to generate sensing signals S_{A}, S_{B} and S_{C} related to the power conversion circuit groups 110A, 110B and 110C to the control circuit 130, wherein the sensing signals S_{A}, S_{B} and S_{C} are related to various characteristics of the power conversion circuit groups 110A, 110B and 110C respectively.

For example, since the power conversion circuit groups 110A, 110B and 110C may have different circuit complexities, parasitic capacitances or other circuit characteristics, output currents I_{A}, I_{B} and I_{C} generated by them may deviate from ideal values in different degrees. Therefore, in some embodiments, the sensing signals S_{A}, S_{B} and S_{C} are respectively related to the output currents I_{A}, I_{B} and I_{C} of the power conversion circuit groups 110A, 110B and 110C.

In another embodiment, since the power conversion circuit groups 110A, 110B and 110C may have different circuit complexities or be arranged at different locations in the power supply 100, their heating/heat dissipation capabilities may be different, causing temperature imbalance in the power supply 100. Therefore, in some embodiments, the sensing signals S_{A}, S_{B} and S_{C} are respectively related to circuit temperatures of the power conversion circuit groups 110A, 110B and 110C.

In conclusion, in some embodiments, the sensing circuit 120 can be implemented with a temperature sensor, a current meter, other components that can sense circuit characteristics or any combination of the above.

The control circuit 130 is coupled to the power conversion circuit groups 110A, 110B, 110C and the sensing circuits 120, configured to receive the sensing signals S_{A}, S_{B} and S_{C} from the sensing circuits 120, and configured to perform a “negative compensation” on the duty cycles of the power conversion circuit groups 110A, 110B and 110C. Specifically, the control circuit 130 calculates compensation values corresponding to the received sensing signals S_{A}, S_{B}, S_{C} and the group output voltages V_{A}, V_{B}, V_{C} output by the power conversion circuit groups 110A, 110B, 110C, and reduces the duty cycles of the power conversion circuit groups 110A, 110B and 110C based on the calculated compensation values.

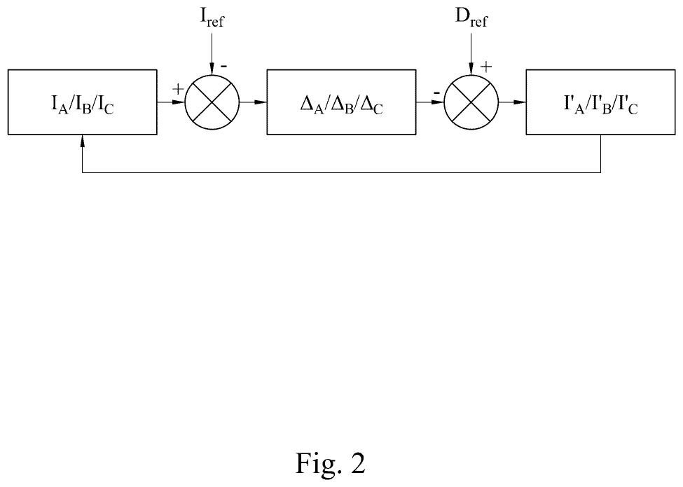

FIG. 2 illustrates detailed operations of the control circuit 130 calculating the compensation values and adjusting the duty cycles. FIG. 2 is a schematic diagram of the control circuit 130 performing negative compensation in accordance with some embodiments of the present disclosure.

In the embodiments of FIG. 2, first, the control circuit 130 calculates a corresponding reference current I_{ref} for each of the power conversion circuit groups 110A, 110B, 110C, and compares the output currents I_{A}, I_{B}, I_{C} of the power conversion circuit groups 110A, 110B, 110C with the corresponding reference current I_{ref} respectively. In some embodiments, the reference current I_{ref} is positively related to the number of power conversion circuit in the corresponding power conversion circuit group.

Next, the control circuit 130 determines the relationships between a current threshold (for example, 5 amps, but the present disclosure is not limited thereto) and the differences between the output currents I_{A}, I_{B}, I_{C} and the reference current I_{ref} respectively. When the difference between one of the output currents I_{A}, I_{B}, I_{C} and the reference current I_{ref} is greater than or equal to a current threshold, the control circuit 130 will determine that it is necessary to perform a negative compensation on the duty cycles of the power conversion circuit groups 110A, 110B and 110C, and calculate the compensation values Δ_{A}, Δ_{B}, Δ_{C} based on the aforementioned differences and the group output voltages V_{A}, V_{B}, V_{C}, wherein the compensation values Δ_{A}, Δ_{B}, Δ_{C} are greater than zero and positively related to the aforementioned differences (for example, the compensation value is equal to the difference multiplied by a specified parameter, or the compensation value is equal to the power of the difference). On the contrary, when the differences between the output currents I_{A}, I_{B}, I_{C} and the reference current I_{ref} are all smaller than the current threshold, the control circuit 130 will determine that there is no need to perform the negative compensation on the power conversion circuit groups 110A, 110B and 110C, and the calculated compensation values Δ_{A}, Δ_{B}, Δ_{C} at this time will be equal to 0.

Finally, the control circuit 130 reduces the duty cycles of the power conversion circuit groups 110A, 110B and 110C based on the calculated compensation values Δ_{A}, Δ_{B} and Δ_{C}. FIG. 3 is a schematic diagram of the operation of the control circuit 130 reducing the duty cycles D_{ref} of the power conversion circuit groups 110A, 110B and 110C in accordance with some embodiments of the present disclosure. After the control circuit 130 performing a negative compensation on the power conversion circuit groups 110A, 110B and 110C, the duty cycles of the power conversion circuit groups 110A, 110B and 110C will be smaller than the original duty cycles D_{ref}. Through this negative compensation manner, since the adjusted duty cycle is smaller than the original duty cycle, the short circuit problem caused by different power conversion circuit groups being activated at the same time can be avoided.

It should be noted that although the initial duty cycles corresponding to the three phases in FIG. 3 are shown to be equal to the duty cycle D_{ref}, the present disclosure is not limited thereto. In some embodiments, the initial duty cycles corresponding to these three phases can be different from each other.

Referring to FIG. 2, the duty cycles are reduced, the power conversion circuit groups 110A, 110B and 110C will convert the input voltage Vin into an adjusted group output voltage according to the new duty cycles, and output adjusted output currents I′_{A}, I′_{B} and I′_{C}. In some embodiments, the adjusted output currents I′_{A}, I′_{B} and I′_{C} are respectively smaller than the output currents I_{A}, I_{B} and I_{C} before adjusted.

In some embodiments, the control circuit 130 further determines the relationships between the current threshold and the differences between the adjusted output currents I′_{A}, I′_{B}, I′_{C} and the reference current I_{ref} respectively. Specifically, when the difference between one of the adjusted output currents I′_{A}, I′_{B}, I′_{C} and the reference current I_{ref} is greater than or equal to the current threshold, the control circuit 130 will determine that it is necessary to perform a negative compensation on the adjusted power conversion circuit groups 110A, 110B and 110C again, and calculate new compensation values (also referred to as second compensation values) based on these differences and the adjusted group output voltage. In some embodiments, the second compensation values are greater than zero and smaller than the compensation values Δ_{A}, Δ_{B}, Δ_{C} used in the previous negative compensation. Therefore, the adjustment range of the control circuit 130 will be from large to small, so as to achieve dense adjustment.

Next, the control circuit 130 reduces the duty cycles of the power conversion circuit groups 110A, 110B and 110C again based on the calculated second compensation values, and so on, until the differences between the output currents of the power conversion circuit groups and the reference current I_{ref} are all smaller than the current threshold.

In the embodiments that the sensing signals S_{A}, S_{B} and S_{C} are related to the circuit temperatures, the control circuit 130 may adjust the duty cycles of the power conversion circuit groups 110A, 110B and 110C in a manner similar to which in FIGS. 2-3. For example, the output currents I_{A}, I_{B} and I_{C} are replaced with the circuit temperatures of the power conversion circuit groups 110A, 110B and 110C, the reference current I_{ref} is replaced with a balance temperature set by the power supply 100, and the current threshold is replaced with a temperature threshold. For the sake of brevity, they will not be repeated here.

Each of the power conversion circuit groups 110A, 110B and 110C shown in FIG. 1 comprises one power conversion circuit, achieving a “symmetric” circuit structure. However, the present disclosure is not limited thereto.

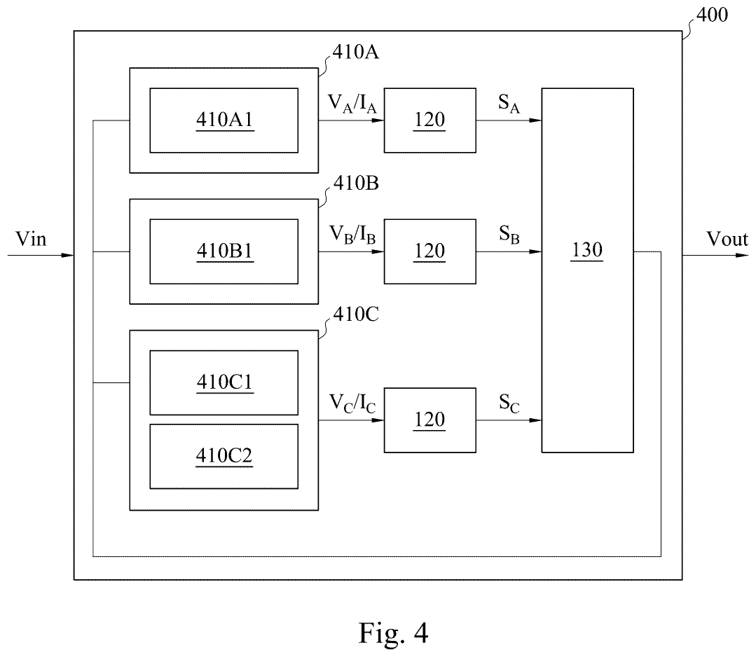

FIG. 4 is a functional block diagram of a power supply 400 in accordance with an embodiment of the present disclosure. Similar to the power supply 100 in FIG. 1, the power supply 400 in FIG. 4 also comprises three power conversion circuit groups (namely, power conversion circuit groups 410A, 410B and 410C), three sensing circuits 120 and a control circuit 130. The difference is that although the power conversion circuit groups 410A and 410B in the power supply 400 also comprise one power conversion circuit (namely, power conversion circuits 410A1 and 410B1) as the power conversion circuit groups 110A and 110B in the power supply 100, the power conversion circuit group 410C comprises power conversion circuits 410C1 and 410C2, wherein the power conversion circuits 410C1 and 410C2 have the same duty cycle and are corresponding to the same phase. In other words, the power conversion circuit groups 410A, 410B and 410C shown in FIG. 4 may each comprise different numbers of at least one power conversion circuit, achieving an “asymmetric” circuit structure.

It should be noted that in the power supply of the present disclosure, the numbers of power conversion circuit group and power conversion circuit within are only examples, and are not intended to limit the present disclosure. Other numbers of power conversion circuit group and other numbers of power conversion circuit are within the scope of the present disclosure. In some embodiments, a power supply may comprise more than three or less than three power conversion circuit groups respectively corresponding to more than three or less than three phases. In some embodiments, a power conversion circuit group may comprise more than two power conversion circuits, and the power conversion circuits in the same power conversion circuit group have the same duty cycle and are corresponding to the same phase.

As mentioned above, the reference current I_{ref} that a power conversion circuit group corresponding to is positively related to the number of power conversion circuit within. Take Table 1 below as an example. Table 1 below lists the reference current I_{ref} corresponding to different configurations of power conversion circuit groups. In the “Power Conversion Circuit Configuration” field, the number of numbers represents the number of power conversion circuit groups, and each number represents the number of power conversion circuit in each power conversion circuit group. For example, “1+1+2” represents three power conversion circuit groups that respectively comprise one power conversion circuit, one power conversion circuit and two power conversion circuits. When the total current is 4 amps, the reference currents I_{ref} of these three power conversion circuit groups are 1 amp, 1 amp and 2 amps respectively.

TABLE 1

| | Power Conversion Circuit Configuration | | |
|---|---|---|---|
| | 1 + 1 + 1 | 1 + 1 + 2 | 2 + 3 + 5 |
| Total Current (amp) | Reference Currents I_{ref} (amp) | | |
| 4 | 1.33, 1.33, 1.33 | 1, 1, 2 | 0.8, 1.2, 2 |
| 10 | 3.33, 3.33, 3.33 | 2.5, 2.5, 5 | 2, 3, 5 |
| 30 | 10, 10, 10 | 7.5, 7.5, 15 | 6, 9, 15 |
| 60 | 20, 20, 20 | 15, 15, 30 | 12, 18, 30 |

Consequently, the power conversion circuit groups 410A, 410B and 410C in the power supply 400 are respectively corresponding to different reference currents I_{ref}, and the control circuit 130 will compare the output currents I_{A}, I_{B} and I_{C} with these reference currents I_{ref}. Take Table 2 below as an example. Table 2 below shows the comparison between the output currents of the power supply 400 before the first negative compensation and the reference currents I_{ref} in accordance with some examples, wherein the current threshold is set to 0.5 amps.

TABLE 2

| | | | Maximum |
|---|---|---|---|
| | Reference | | difference from |
| Total Current | Currents I_{ref} | Output Currents I_{A}, I_{B}, | reference currents |
| (amp) | (amp) | I_{C} (amp) | (amp) |
| 4 | 1, 1, 2 | 1.53, 1.06, 2.38 | 0.53 |
| 10 | 2.5, 2.5, 5 | 2.88, 2.72, 5.06 | 0.38 |
| 30 | 7.5, 7.5, 15 | 7.97, 8.06, 15.28 | 0.56 |
| 60 | 15, 15, 30 | 15.16, 15.61, 30.28 | 0.61 |

It can be seen from Table 2 that the maximum difference between the output currents I_{A}, I_{B}, I_{C} and the reference currents I_{ref} will exceed the current threshold when the total current is 4, 30 and 60 amps. Therefore, the control circuit 130 will reduce the duty cycles of the power conversion circuit groups 410A, 410B and 410C according to the negative compensation described above, and compare the adjusted output currents I′_{A}, I′_{B}, I′_{C} with the reference currents I_{ref}. Take Table 3 below as an example. Table 3 below shows the comparison between the output currents of the power supply 400 after the first negative compensation and the reference currents I_{ref} in accordance with some examples.

TABLE 3

| | | | Maximum |
|---|---|---|---|
| | Reference | Adjusted Output | difference from |
| Total Current | Currents I_{ref} | Currents I′_{A}, I′_{B}, I′_{C} | reference currents |
| (amp) | (amp) | (amp) | (amp) |
| 4 | 1, 1, 2 | 1.32, 1.03, 2.12 | 0.32 |
| 10 | 2.5, 2.5, 5 | 2.8, 2.69, 5.02 | 0.3 |
| 30 | 7.5, 7.5, 15 | 7.65, 7.89, 15.11 | 0.39 |
| 60 | 15, 15, 30 | 15.1, 15.38, 30.2 | 0.38 |

It can be seen from Table 3 that after performing negative compensation on the power conversion circuit groups 410A, 410B and 410C of the power supply 400, the maximum difference between their output currents and the reference currents has become smaller than the current threshold. Therefore, the control circuit 130 will determine that there is no need to perform negative compensation, and at this time, the duty cycles of the power conversion circuit groups 410A, 410B and 410C have been adjusted to the ideal state.

In addition, since some circuit characteristics of the power conversion circuit may be dynamic, even if the adjusted output currents have reached the ideal range, they may still exceed the specification again after a period of time. Therefore, in some embodiments, the sensing circuits 120 of the power supplies 100 and 400 sense all power conversion circuit groups to generate sensing signals every time an adjustment period (for example, ten minutes) passes, thereby achieving “automation” of the adjustment of the power supply.

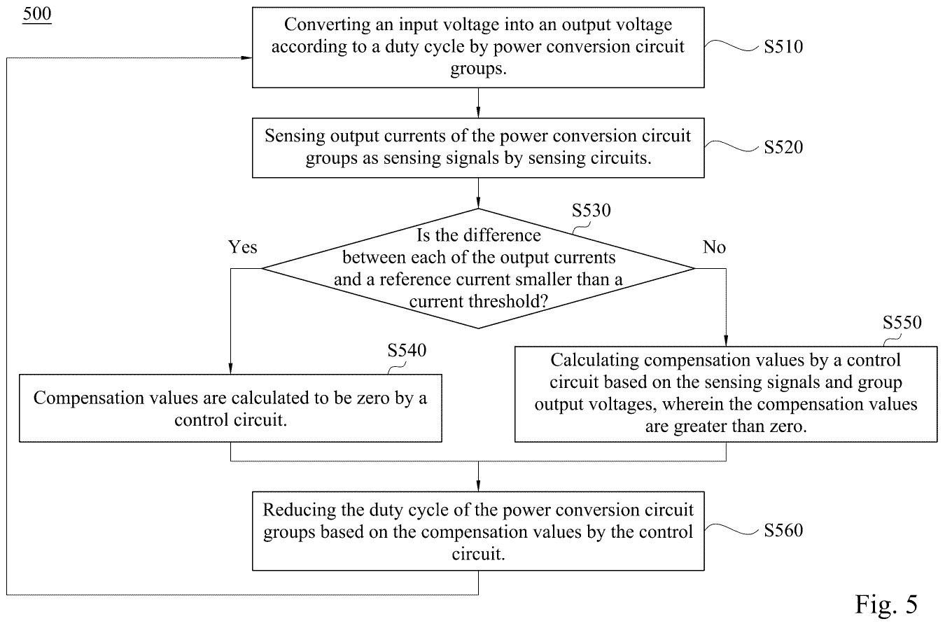

FIG. 5 is a flowchart of a power distribution method 500 in accordance with some embodiments of the present disclosure. The power distribution method 500 is suitable for a power supply (for example, the power supply 100 of FIG. 1 and the power supply 400 in FIG. 4) and comprises activities S510, S520, S530, S540, S550 and S560.

In S510, an input voltage is converted into an output voltage according to a duty cycle by a plurality of power conversion circuit groups (for example, the power conversion circuit groups 410A, 410B and 410C) of a power supply. Next, S520 will be performed.

In S520, output currents of the power conversion circuit groups are sensed as sensing signals by sensing circuits (for example, the sensing circuit 120) of the power supply. Next, S530 will be performed.

In S530, a control circuit (for example, the control circuit 130) of the power supply determines whether the difference between each of the output currents and a reference current is smaller than a current threshold. When the differences between the output currents and the reference current are all smaller than the current threshold, S540 will be performed next; when at least one of the differences between the output currents and the reference current is greater than or equal to the current threshold, S550 will be performed next.

In S540, compensation values corresponding to the power conversion circuit groups are calculated by the control circuit, wherein the compensation values are zero. In S550, the compensation values corresponding to the power conversion circuit groups are calculated by the control circuit based on the sensing signals and group output voltages, wherein the compensation values are greater than zero.

S560 will be performed after S540 or S550. In S560, the duty cycles of the power conversion circuit groups are reduced by the control circuit based on the compensation values calculated in S540, S550. After S560, when the control circuit performs a negative compensation on the power conversion circuit groups, or an adjustment period passes, S510 will be performed again.

It should be noted that as mentioned above, the sensing signals used in the power distribution method 500 can be related to the circuit temperatures. At this time, the output currents used in the power distribution method 500 are replaced with the circuit temperatures of the power conversion circuit groups, the reference current is replaced with the balance temperature set by the power supply, and the current threshold is replaced with the temperature threshold. For the sake of brevity, they will not be repeated here.

In conclusion, through the power supplies 100, 400 and the power distribution method 500 of the present disclosure, when the output current exceeds the ideal value to a certain degree, the duty cycles of the circuits can be automatically and gradually adjusted with negative compensation, thereby avoiding short circuit problems while keeping the power supply operate normally. Furthermore, the power supply (for example, the power supply 400) provided in the present disclosure can also map each phase to various numbers of more than one power conversion circuits, thereby achieving an asymmetric circuit structure.

The above various embodiments of the present disclosure. It will be apparent to those skilled in the art that various modifications and variations can be made to the structure of the present disclosure without departing from the scope or spirit of the present disclosure. In view of the foregoing, it is intended that the present disclosure cover modifications and variations of this disclosure provided they fall within the scope of the following claims and their equivalents.

The disclosed systems and methods are not limited to the specific embodiments described herein. Rather, components of the systems or activities of the methods may be utilized independently and separately from other described components or activities.

This written description uses examples to disclose various embodiments, which include the best mode, to enable any person skilled in the art to practice those embodiments, including making and using any devices or systems and performing any incorporated methods. The patentable scope is defined by the claims and may include other examples that occur to those skilled in the art. Such other examples are intended to be within the scope of the claims if they have structural elements that do not differ from the literal language of the claims, or if they include equivalent structural elements with insubstantial differences form the literal language of the claims.

1. A power supply, comprising:
a plurality of power conversion circuit groups, wherein each of the plurality of power conversion circuit groups comprises at least one power conversion circuit, and is configured to convert an input voltage into an output voltage according to a duty cycle;
a plurality of sensing circuits, respectively coupled to the plurality of power conversion circuit groups, and configured to sense the plurality of power conversion circuit groups to generate a plurality of sensing signals; and
a control circuit, coupled to the plurality of power conversion circuit groups and the plurality of sensing circuits, configured to:
calculate a plurality of compensation values based on the plurality of sensing signals and a plurality of group output voltages, and
reduce the duty cycle of the plurality of power conversion circuit groups based on the plurality of compensation values,
wherein the plurality of group output voltages correspond to a plurality of phases, and the plurality of phases correspond to the plurality of power conversion circuit groups.

2. The power supply of claim 1, wherein:
the duty cycles of each of the at least one power conversion circuit of any one of the plurality of power conversion circuit groups are the same, and
the at least one power conversion circuit of any one of the plurality of power conversion circuit groups corresponds to the respective phase of the plurality of phases.

3. The power supply of claim 1, wherein the at least one power conversion circuit is arranged in the power supply in a single in-line package.

4. The power supply of claim 1, wherein the plurality of sensing signals are related to a plurality of circuit temperatures of the plurality of power conversion circuit groups, and when a difference between one of the plurality of circuit temperatures and a balance temperature is greater than or equal to a temperature threshold, the plurality of compensation values are greater than zero and positively related to the difference between the one of the plurality of circuit temperatures and the balance temperature.

5. The power supply of claim 4, wherein when the differences between each of the plurality of circuit temperatures and the balance temperature are smaller than the temperature threshold, the plurality of compensation values are equal to zero.

6. The power supply of claim 1, wherein:
the plurality of sensing signals are related to a plurality of output currents of the plurality of power conversion circuit groups, and when a difference between one of the plurality of output currents and a reference current is greater than or equal to a current threshold, the plurality of compensation values are greater than zero and positively related to the difference between the one of the plurality of output currents and the reference current, and
the reference current is positively related to the number of the at least one power conversion circuit in a corresponding one of the plurality of power conversion circuit groups.

7. The power supply of claim 6, wherein:
after the control circuit reduces the duty cycle of the plurality of power conversion circuit groups based on the plurality of compensation values, the plurality of power conversion circuit groups are configured to convert the input voltage into an adjusted output voltage and output a plurality of adjusted output currents, and
the plurality of sensing signals are related to the plurality of adjusted output currents, and the plurality of adjusted output currents are smaller than the plurality of output currents.

8. The power supply of claim 7, wherein:
when a difference between one of the plurality of adjusted output currents and the reference current is greater than or equal to the current threshold, the control circuit is further configured to calculate a plurality of second compensation values based on the plurality of sensing signals and a plurality of adjusted group output voltages, and configured to reduce the duty cycle of the plurality of power conversion circuit groups based on the plurality of second compensation values, and
the plurality of second compensation values are positively related to the difference between the one of the plurality of adjusted output currents and the reference current, and the plurality of second compensation values are smaller than the plurality of compensation values and greater than zero.

9. The power supply of claim 6, wherein when the differences between each of the plurality of output currents and the reference current are smaller than the current threshold, the plurality of compensation values are equal to zero.

10. The power supply of claim 1, wherein the plurality of sensing circuits are further configured to sense the plurality of power conversion circuit groups to generate the plurality of sensing signals at an interval of an adjustment period.

11. A power distribution method for a power supply, the power distribution method comprising:
converting, by a plurality of power conversion circuit groups of the power supply, an input voltage into an output voltage, according to a duty cycle;
sensing, by a plurality of sensing circuits of the power supply, the plurality of power conversion circuit groups, to generate a plurality of sensing signals;
calculating, by a control circuit of the power supply, a plurality of compensation values, based on the plurality of sensing signals and a plurality of group output voltages; and
reducing, by the control circuit, the duty cycle of the plurality of power conversion circuit groups, based on the plurality of compensation values, wherein:
each of the plurality of power conversion circuit groups comprises at least one power conversion circuit,
the plurality of group output voltages correspond to a plurality of phases, and
the plurality of phases correspond to the plurality of power conversion circuit groups.

12. The power distribution method of claim 11, wherein:
the duty cycles of each of the at least one power conversion circuit of any one of the plurality of power conversion circuit groups are the same, and
the at least one power conversion circuit of the any one of the plurality of power conversion circuit groups corresponds to the same one of the plurality of phases.

13. The power distribution method of claim 11, wherein the at least one power conversion circuit is arranged in the power supply in a single in-line package.

14. The power distribution method of claim 11, wherein the sensing, by the plurality of sensing circuits of the power supply, the plurality of power conversion circuit groups, to generate the plurality of sensing signals, comprises:
sensing, by the plurality of sensing circuits, a plurality of circuit temperatures of the plurality of power conversion circuit groups, as the plurality of sensing signals,
wherein in response to a difference between one of the plurality of circuit temperatures and a balance temperature being greater than or equal to a temperature threshold, the plurality of compensation values are greater than zero and positively related to the difference between the one of the plurality of circuit temperatures and the balance temperature.

15. The power distribution method of claim 14, wherein in response to the differences between each of the plurality of circuit temperatures and the balance temperature being smaller than the temperature threshold, the plurality of compensation values are equal to zero.

16. The power distribution method of claim 11, wherein sensing, by the plurality of sensing circuits of the power supply, the plurality of power conversion circuit groups, to generate the plurality of sensing signals comprises:
sensing, by the plurality of sensing circuits, a plurality of output currents output by the plurality of power conversion circuit groups, as the plurality of sensing signals, wherein:
in response to a difference between one of the plurality of output currents and a reference current being greater than or equal to a current threshold, the plurality of compensation values are greater than zero and positively related to the difference between the one of the plurality of output currents and the reference current, and
the reference current is positively related to the number of the at least one power conversion circuit in a corresponding one of the plurality of power conversion circuit groups.

17. The power distribution method of claim 16, wherein after reducing, by the control circuit, the duty cycle of the plurality of power conversion circuit groups, based on the plurality of compensation values, the power distribution method further comprises:
converting, by the plurality of power conversion circuit groups, the input voltage into an adjusted output voltage;
outputting, by the plurality of power conversion circuit groups, a plurality of adjusted output currents; and
sensing, by the plurality of sensing circuits, the plurality of adjusted output currents output by the plurality of power conversion circuit groups, as the plurality of sensing signals, wherein the plurality of adjusted output currents are smaller than the plurality of output currents.

18. The power distribution method of claim 17, wherein after sensing, by the plurality of sensing circuits, the plurality of adjusted output currents output by the plurality of power conversion circuit groups, as the plurality of sensing signals, the power distribution method further comprises:
in response to a difference between one of the plurality of adjusted output currents and the reference current being greater than or equal to the current threshold:
calculating, by the control circuit, a plurality of second compensation values, based on the plurality of sensing signals and a plurality of adjusted group output voltages; and
reducing, by the control circuit, the duty cycle of the plurality of power conversion circuit groups, based on the plurality of second compensation values,
wherein the plurality of second compensation values are positively related to the difference between the one of the plurality of adjusted output currents and the reference current, and the plurality of second compensation values are smaller than the plurality of compensation values and greater than zero.

19. The power distribution method of claim 16, wherein in response to the differences between each of the plurality of output currents and the reference current being smaller than the current threshold, the plurality of compensation values are equal to zero.

20. The power distribution method of claim 11, wherein sensing, by the plurality of sensing circuits of the power supply, the plurality of power conversion circuit groups, so as to generate the plurality of sensing signals further comprises:
sensing, by the plurality of sensing circuits, the plurality of power conversion circuit groups, at an interval of an adjustment period, so as to generate the plurality of sensing signals.
